(19) United States
(12) Patent Application Publication
(10) Pub. No.: US 2009/0159977 A1
(43) Pub. Date: Jun. 25, 2009

(54) Semiconductor device having gate electrode including contact portion on element isolation region

(75) Inventor: Kazuyuki Itou, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 12/314,230

(22) Filed: Dec. 5, 2008

(30) Foreign Application Priority Data
Dec. 21, 2007 (JP) 2007-329857

(51) Int. Cl. H01L 27/088

(52) U.S. Cl. 257/368; 257/E27.06

(57) ABSTRACT

A semiconductor device has gate electrodes disposed in plural columns, respectively, over a semiconductor substrate in such a way as to be lined up along the direction of a gate length, and a gate connection portion provided in the same layer where the respective gate electrodes in the plural columns are placed, for electrically connecting the gate electrodes with each other. The gate connection portion includes a protrusion protruding outward in the direction of the gate length from the gate electrode positioned at the outermost ends of the gate electrodes disposed in the plural columns, respectively.

### BACKGROUND OF THE INVENTION

1. Field of the Invention

The invention relates to a semiconductor device having gate electrodes disposed in plural columns lined up along the direction of a gate length, respectively.

2. Description of Related Art

In connection with this kind of technology, the gate electrode has a direct effect on transistor characteristics (referred to as Tr characteristics hereinafter), and fine control is required of its line width size (gate length), and shape.

In the case of forming a gate pattern by photolithography, if the size of a resist pattern becomes less than an exposure light wavelength, then this will produce the so-called optical proximity effect whereby the resist pattern comes to be deviated from that at the time of designing, thereby causing a problem.

In contrast to the case described as above, in Patent Document (Japanese Patent Application Laid Open No. 2006-156778) referred to hereunder, there has been disclosed the invention wherein fluctuation in gate length is lessened by devising a novel shape for a gate pattern even in the case where the optical proximity effect is produced. In Patent Document, it has been disclosed that a gate interconnection on a device separation insulating film adjacent to one side of a diffusion layer is provided with a large-width region (contact part) for connection with a contact plug while a dummy contact part is provided on a device separation insulating film adjacent to the other side of the diffusion layer, that is, on a gate interconnection extending toward the opposite side from the contact part with the diffusion layer sandwiched therebetween.

It has been described that by so doing, non-uniformity between one end of a gate electrode disposed over the diffusion layer, where the contact part is provided, in the longitudinal direction thereof (in the direction of a gate width), and the other end thereof, where the contact part is not provided, can be improved.

### SUMMARY

However, the inventor, et al. have found out that there occurs a problem of the Tr characteristics varying by the gate electrode even in the case of the invention according to Patent Document if a gate pattern includes gate electrodes disposed in the plural columns, respectively, as shown in FIGS. 3, 4 of the Patent Document.

FIG. 7 is a schematic plan view showing an example of a conventional gate pattern, corresponding to FIGS. 3, 4, shown in the Patent Document described as above.

A semiconductor device 1000 includes a channel region (a diffusion layer 1050) in an impurity diffusion layer formed in a semiconductor substrate such as a silicon substrate, and so forth, and a device separation insulating region (device separation insulating film 1060). The diffusion layer 1050 serves as the channel region of a transistor, a source and a drain thereof.

As shown in FIG. 7, gate electrodes 1010 disposed in plural columns (four columns in the figure), respectively, and lined up in the direction of a gate length are formed so as to spread across the channel region of the diffusion layer 1050, and the device separation insulating film 1060. And the gate electrodes 1010 are electrically continuous with each other through the intermediary of a gate connection part 1030, and are further electrically continuous with interconnections (not shown) in an upper layer via contacts 1040 provided over the gate connection part 30.

With the example of the conventional gate pattern shown in FIG. 7, a nonuniform bulge (corner rounding 1080) has occurred to each of the four gate electrodes 1010, owing to influence of the optical proximity effect, on the gate connection part 30. More specifically, the corner rounding 1080 occurring to a corner between the gate electrode, and the gate connection part has been formed only on one side of each of the two gate electrodes 1010b among the four gate electrodes 1010, positioned on the outer side, while the corner rounding 1080 has been formed on both sides of each of the two gate electrodes 1010a, positioned on the inner side.

As a result, the two gate electrodes 1010a are each formed so as to be greater in respect of the line width in the vicinity of the corner than each of the two gate electrodes 1010b.

In this connection, it will be appreciated that if the line width of the gate electrode serving as a flow path of gate current is large, then resistance against the gate current becomes smaller, so that a voltage drop that occurs upon the gate current passing therethrough will decrease. Conversely, if the line width of the gate electrode is small, then the resistance becomes greater, so that the voltage drop due to the gate current passing therethrough will increase. Accordingly, if the gate connection part 30 is at an equivalent potential, then a gate voltage imposed from the gate electrode 1010b smaller in the line width onto the channel region will be lower than a gate voltage imposed from the gate electrode 1010a greater in the line width onto the channel region. As a result, there occurs the problem of fluctuation in the Tr characteristics of the semiconductor device 1000.

Further, if the diffusion layer 1050 is overlapped by the corner rounding 1080, as shown in the figure, in particular, then this will have a pronounced effect on the Tr characteristics because the width (gate length) of each of the gate electrodes 1010, over the diffusion layer 1050, becomes greater.

In FIG. 7, with the gate electrode 1010b positioned on the outer side, since the diffusion layer 1050 is overlapped by the corner rounding 1080, on one side of the gate electrode 1010b, in the direction of the line width, the gate length of the gate electrode 1010b is slightly greater than a gate length L as designed.

On the other hand, with each of the gate electrodes 1010a, positioned on the inner side, since the diffusion layer 1050 is overlapped by the corner rounding 1080, on both sides of the gate electrode 1010a, in the direction of the line width, the gate length of the gate electrode 1010a becomes greater than the gate length L.

As a result, there occurs non-uniformity in the gate length by the gate electrode of the respective gate electrodes 1010 disposed in the plural columns, resulting in occurrence of fluctuation in the Tr characteristics.

An invention provides in its one aspect a semiconductor device having gate electrodes disposed in plural columns, respectively, over a semiconductor substrate, so as to be lined up along the direction of a gate length, and a gate connection part provided in the same layer where the respective gate electrodes in the plural columns are placed, for electrically connecting the gate electrodes with each other, wherein the gate connection part includes a protrusion protruding outward in the direction of the gate length from the gate electrode positioned at the outermost end of the plural columns.

In the case of the semiconductor device according to the aspect of the invention, with respect to the gate electrode positioned on the outermost side of the respective gate electrodes in the plural columns, provided in parallel, a corner is formed on the respective sides thereof, in the direction of a width, so that it is possible to check variation in line width from the other gate electrodes positioned on the inner side. By so doing, it is possible to obtain uniform Tr characteristics.

### BRIEF DESCRIPTION OF THE DRAWINGS

The above and other exemplary aspects, advantages and features of the present invention will be more apparent from the following description of certain exemplary embodiments taken in conjunction with the accompanying drawings, in which:

FIG. 1 is a schematic plan view showing an example of a semiconductor device according to a first exemplary embodiment of the invention;

FIG. 2A is a sectional arrow view taken on line A-A in FIG. 1, and FIG. 2B is a sectional view taken on line B-B in FIG. 1;

FIG. 3 is a schematic plan view showing an example of a semiconductor device according to a second exemplary embodiment of the invention;

FIG. 4 is a schematic plan view showing an example of a semiconductor device according to a third exemplary embodiment of the invention;

FIG. 5 is a schematic plan view showing an example of a semiconductor device according to a fourth exemplary embodiment of the invention;

FIG. 6 is a schematic plan view showing an example of a semiconductor device according to a fifth exemplary embodiment of the invention; and

FIG. 7 is a schematic plan view showing an example of a conventional gate pattern.

### DETAILED DESCRIPTION OF THE EXEMPLARY EMBODIMENTS

### First Exemplary Embodiment

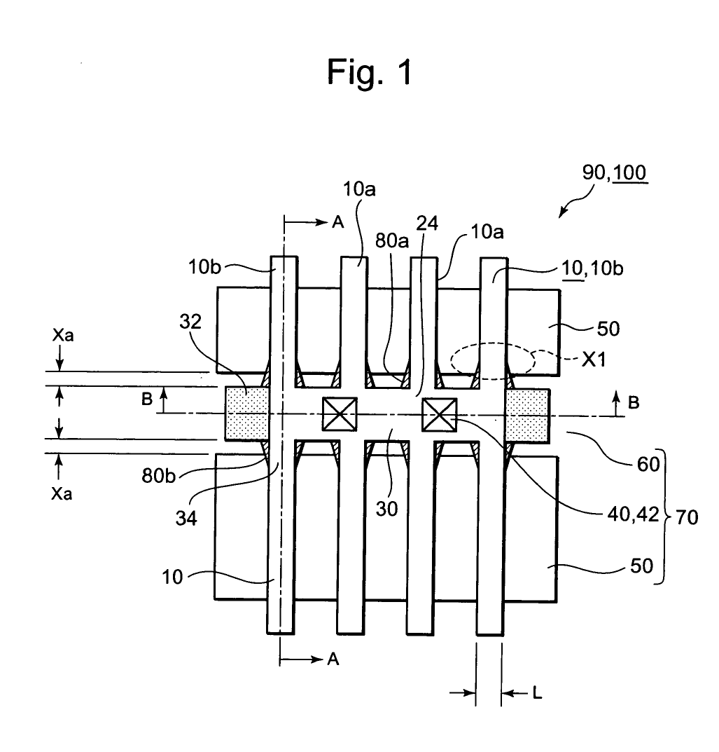

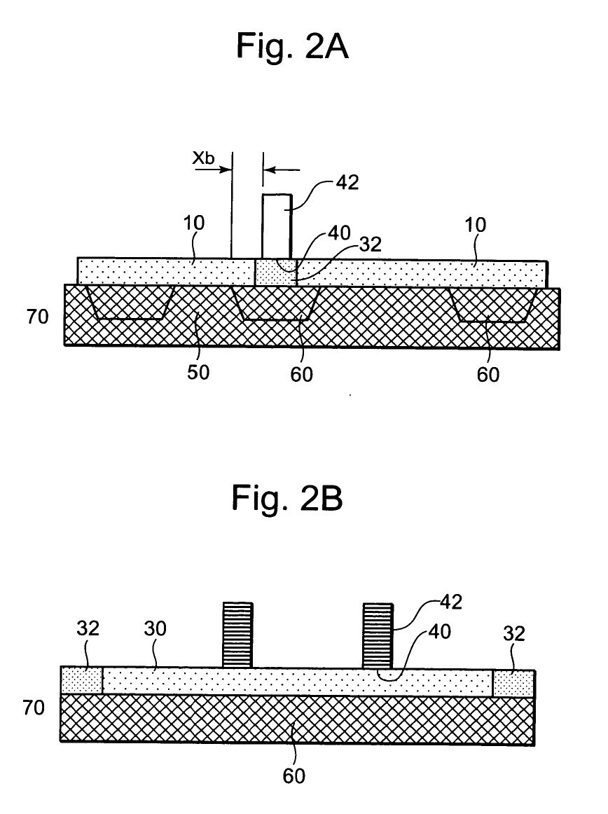

FIG. 1 is a schematic plan view showing an example of a semiconductor device 100 according to a first exemplary embodiment of the invention. FIG. 2A is a sectional arrow view taken on line A-A in FIG. 1, and FIG. 2B is a sectional view taken on line B-B in FIG. 1.

First, there is described an overview of the semiconductor device 100 according to the present embodiment.

The semiconductor device 100 includes gate electrodes 10 disposed in plural columns, respectively, over a semiconductor substrate 70, so as to be lined up along the direction of a gate length, and a gate connection part 30 provided in the same layer where the gate electrodes 10 are placed, for electrically connecting the gate electrodes 10 with each other,

The gate connection part 30 according to the present embodiment has a feature in that the gate connection part 30 includes a protrusion 32 protruding outward in the direction of the gate length from the gate electrode 10b positioned at the outermost end of the plural columns.

Now, the semiconductor device 100 according to the present embodiment is described in more detail hereinafter.

With the semiconductor device 100, a transistor structure (a first transistor 90) is made up of the respective gate electrodes 10 disposed in the plural columns, respectively, over the semiconductor substrate 70, and the gate connection part 30 for electrically connecting the gate electrodes 10 with each other.

The gate electrodes 10 shown in FIG. 1 are provided in a comb-like state so as to be disposed in four columns lined up in the direction of the gate length, directly, or indirectly through the intermediary of an intervening layer, over a diffusion layer 50. Such a layout is used in the case of, for example, obtaining plural outputs out of one input.

The number of the gate electrodes 10 to be connected together by the gate connection part 30 is not less than three, and there is no particular limitation thereto as long as there exist the gate electrodes 10b on the outer sides of the layout, respectively, and the gate electrode 10a on the inner side of the layout.

The semiconductor substrate 70 is provided with one, or plural channel regions (diffusion layers 50) in an impurity diffusion layer, and one, or plural device separation insulating regions (device separation insulating films 60), adjacent thereto. With the present embodiment, two of the diffusion layers 50 are provided so as to oppose each other along the direction of a gate width (the vertical direction in the figure), and the device separation insulating film 60 is provided between the respective diffusion layers 50, and around the respective diffusion layers 50.

The respective gate electrodes 10 disposed in the plural columns are formed so as to spread across over the diffusion layers 50, and the device separation insulating films 60, respectively. Meanwhile, the gate connection part 30 is provided over the device separation insulating film 60.

The gate electrode 10, and the gate connection part 30 provided in the same layer where the gate electrodes 10 are placed are composed of an electrically conductive material such as a polysilicon film, poly-silicide film, poly-SiGe film, and so forth. Besides the above, use may be made of a metal gate using a metallic material such as tungsten, and so forth.

The gate connection part 30 has the protrusion 32 protruding outward in the direction of the gate length from each of the gate electrodes 10b positioned at respective ends of the gate electrodes 10 disposed in the plural columns, respectively.

Accordingly, an outer corner 34 is formed at an intersection between the gate electrode 10b on the outer side, and the protrusion 32.

On the other hand, an inner corner 24 is formed at each of intersections formed between a region of the gate connection part 30, excluding the protrusions 32, that is, a region (bridging part) sandwiched between the gate electrodes 10b positioned in the columns at the respective ends, and the gate electrodes 10a, 10b, respectively.

Corner roundings 80a, 80b, extending from the device separation insulating film 60 toward the diffusion layer 50, are each formed at the corner (the inner corner 24, the outer corner 34) between the gate electrode 10 and the gate connection part 30 owing to the optical proximity effect.

In the case of the present invention, the corner roundings 80a, 80b each reach the upper part of the diffusion layer 50 to be formed to such a magnitude as overlapping the same.

The protrusion 32 may be either electrically conductive, or electrically nonconductive, however, if the protrusion 32 is formed of the same kind of electrically conductive material as that for the gate electrode 10, and the gate connection part 30, this will enable the protrusion 32 to be formed in the same film forming step as a step for forming the gate electrode 10, and the gate connection part 30.

Further, if the protrusion 32 is provided in the same layer as the layer for the gate electrodes 10, and the gate connection part 30, then this will cause the corner rounding 80b to occur to the outer corners 34 upon formation of respective patterns of the gate electrodes 10, and the gate connection part 30.

The gate connection part 30 is extended over the top of the device separation insulating film 60, in a direction intersecting the respective gate electrodes 10 disposed in the plural columns. With the present embodiment of the invention, the gate electrodes 10 are all lined up in the direction of the gate length so as to be parallel with each other, and the gate connection part 30 is formed so as to be extended in a direction orthogonal to the gate electrodes 10, that is, in the direction of the gate length.

A boundary line between the diffusion layer 50, and the device separation insulating film 60 extends in the direction of the gate length, and is parallel with the gate connection part 30. Accordingly, a distance (Xa shown in FIG. 1) between the diffusion layer 50, and the gate connection part 30, as seen in a plan view, at any of the corners, is an equal distance.

Accordingly, the corner rounding 80b formed on the outer corner 34 will be in a shape congruent to, or mirror-symmetrical to the corner rounding 80a formed on the inner corner 24.

Thus, the corner rounding 80a, and the corner rounding 80b, identical in shape and size to each other, are formed on both sides of the gate electrodes 10 arranged in the comb-like state, in the direction of the gate length.

In FIG. 1, the corner rounding 80b formed on the outer corner 34, and the corner rounding 80a formed on the inner corner 24 are each shown in a triangular shape as distinguished from the gate electrode 10, and the gate connection part 30, for the purpose of high-lighting. However, it is to be pointed out that a distinct boundary is not formed between each of the corner roundings 80a, 80b as actually formed, and the gate electrode 10, or the gate connection part 30. The corner roundings 80a, 80b, as actually formed, each correspond to a portion of the gate electrode 10, larger in width, formed due to gradual increase in the width thereof, before reaching the gate connection part 30.

Further, in FIG. 1, for highlight the protrusion 32, the protrusion 32 is shown as distinguished from the gate electrode 10, and the gate connection part 30, however, if the protrusion 32 is formed of the same kind of material as that for the gate connection part 30, as described in the foregoing, the boundary therebetween is not necessarily definitely formed. The protrusion 32 is identified as a portion of the gate connection part 30, protruding outward from a phantom line obtained by extending the outer edge of the gate electrode 10 positioned at the outer end from the diffusion layer 50 to the device separation insulating film 60.

With the semiconductor device 100, the corner roundings 80a, 80b are each formed to a size sufficient to reach the upper part of the diffusion layer 50. In other words, respective dimensions of the corner roundings 80a, 80b, formed on the inner corner 24, and the outer corner 34, respectively, in the direction of the gate width, are greater than the distance between the diffusion layer 50, and the gate connection part 30, as seen in a plan view.

Accordingly, as described in the foregoing, the gate length L of the gate electrode 10, on one end side of the diffusion layer 50, proximate to the gate connection part 30, becomes longer, and the gate length L on the other end side of the diffusion layer 50 (on the side thereof, away from the gate connection part 30) becomes shorter. This is because the respective gate electrodes 10 in regions (regions X1 in FIG. 1) where the corner roundings 80a, 80b are formed, over the diffusion layer 50, respectively, are formed greater in width, that is, the respective gate electrodes 10 appear to be in a state such that the gate length L is increased since the corner roundings 80a, 80b each are formed of the same kind of electrically conductive material as material for the gate electrode 10.

From a viewpoint described as above, a length of the protrusion 32, protruding in the direction of the gate length, is preferably rendered sufficiently large as compared with magnitude of a bulge of the gate electrode 10, caused by the corner rounding 80b. Further, a distance between the protrusion 32, and the diffusion layer 50, as seen in the plan view, is preferably rendered equal to the distance between the gate connection part 30, and the diffusion layer 50, as seen in the plan view, that is, the protrusion 32 is preferably formed by extending the gate connection part 30, as it is, in the direction of the gate length.

As for specific dimensions, the gate length L can be in a range of, for example, 30 to 100 nm. The length of the protrusion 32, protruding in the direction of the gate length, can be rendered 1 to 5 times as large as the gate length L. If the protrusion 32 as described is provided, then this will enable the corner rounding 80b to be satisfactorily formed on the outer corner 34, further enabling the corner rounding 80b to be equivalent in dimension to the corner rounding 80a formed on the inner corner 24. Furthermore, if the length of the protrusion 32, protruding in the direction of the gate length, is kept in a range from 1 to 2.5 times as large as the gate length L, this will check the gate connection part 30 from protruding beyond the diffusion layer 50, in the direction of the gate length, so that a pattern area of the first transistor 90 is prevented from becoming excessively large.

Further, the distance Xa between the protrusion 32, and the diffusion layer 50 can be rendered 1 to 3 times as large as the gate length L, preferably, 1 to 1.5 times as large as the gate length L.

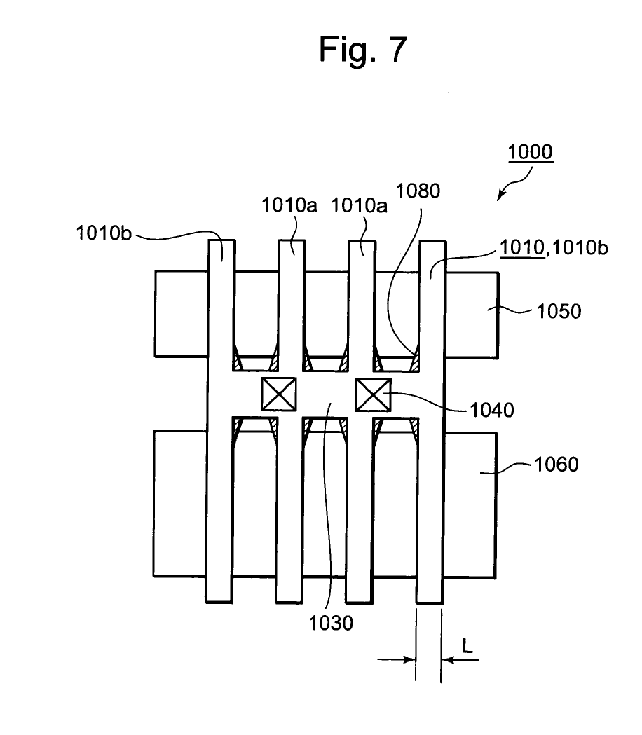

With the semiconductor device disclosed in Patent Document 1, the main factor for causing the fluctuation in the Tr characteristics has been that the corner rounding has not occurred to the gate electrodes 1010b (refer to FIG. 7) positioned on the outer side of the gate electrodes provided so as to be lined up side by side. In contrast, with the semiconductor device 100 according to the present embodiment, each of the gate electrodes 10b positioned on the outer side is provided with the outer corner 34, to which the corner rounding 80b occurs.

The gate electrode 10 is electrically connected to an interconnection (not shown) provided in an upper layer of the gate electrode 10 via a contact part 40 provided in the gate connection part 30.

The contact part 40 according to the present embodiment is provided inside of the gate electrodes 10b positioned at the respective ends of the gate electrodes 10 disposed in the plural columns, respectively.

The contact part 40 is a region virtually partitioned on the top of the gate connection part 30, corresponding to a footprint of a contact plug 42 having electrical conductivity.

There is no particular limitation to position, dimensions, shape, and the number of pieces with respect to the contact plug 42, however, with the present embodiment of the invention, two pieces of the contact plugs 42, in the shape of a rectangular pillar, respectively, are lined up side by side in the direction of the gate length, as shown in FIGS. 1, and 2.

In this connection, the contact plug 42 generally has a dimension (width dimension) in the direction of the gate length, greater in width than the gate electrode 10. Accordingly, a dimension of the contact part 40, in the direction of the gate length, is rendered greater in width than the gate electrode 10.

Meanwhile, the gate connection part 30 for electrically connecting the gate electrodes 10 with each other has a sufficient dimension in the direction of the gate length within the region between the gate electrodes 10b positioned at the respective ends of those gate electrodes 10. Accordingly, with the present embodiment of the invention, the contact parts 40 are disposed on the top of the gate connection part 30, and inside the region between the gate electrodes 10b positioned at the respective ends of those gate electrodes 10.

An electrical conduction path leading from the gate electrode 10 to the interconnection (not shown) provided in the upper layer via the contact part 40 and the contact plug 42 is made up of the gate connection part 30 (the bridging part), excluding the respective protrusions 32. That is, the protrusion 32 according to the present embodiment of the invention is not a constituent of a semiconductor circuit, but is the so-called dummy gate for use in acquiring the outer corner 34, and the corner rounding 80b.

Now, there is described an operation effect of the semiconductor device 100 according to the present embodiment of the invention.

In the case of the semiconductor device 100 according to the present embodiment, with respect to the gate electrode positioned on the outermost sides of the gate electrodes in the plural columns, provided in parallel, a corner is formed on both sides thereof, in the direction of a width.

As a result, the gate electrodes positioned on the outer sides, respectively, and the gate electrodes positioned inside of the plural columns are fabricated under identical conditions during a process of forming a gate pattern.

Accordingly, in the case of the corner rounding occurring to the corners (the inner corner, and the outer corner) due to the optical proximity effect, a uniform increase in the line width will occur to the gate electrodes positioned on the outer sides, respectively, and the gate electrodes positioned inside of the plural columns. In so doing, it is possible to equalize a degree of voltage drop by the gate electrode regardless of whether the optical proximity effect occurs or not, thereby imposing an equal gate voltage onto the channel region.

Further, even when a corner rounding is large in dimensions, and the corner rounding overlaps the diffusion layer 50, an overlapping part occurs to both sides of the line width of the gate electrodes positioned on the outer sides, respectively, and to both sides of the gate electrodes positioned on the inner side. Accordingly, gate lengths of the gate electrodes positioned on the inner side as well as the gate electrodes positioned on the outer sides, respectively, are uniformly increased at the overlapping part, so that there occurs no fluctuation in the Tr characteristics of the semiconductor device 100.

It is possible to equalize the line width with respect to all the gate electrodes by providing the protrusion 32 on both sides of the gate connection part 30, as shown in FIG. 1, that is, by providing the protrusion 32 in such a way as to be protruded outward in the direction of the gate length from the gate electrodes 10b positioned at the respective ends of the plural columns. Accordingly, the semiconductor device 100 according to the present embodiment has a structure where fluctuation in the Tr characteristics is less even in the case of variation in various process factors such as an exposure light wavelength, a distance between a mask pattern and a photo resist, whether an inner cell is present or not, and so forth.

Further, with the semiconductor device 100 according to the present embodiment, the respective gate electrodes 10 in the plural columns are formed so as to spread across the diffusion layers 50, and the device separation insulating film 60, and the corner roundings 80a, 80b, extending up to the diffusion layer 50, are formed at the respective corners (the inner corners 24, the outer corners 34) between the respective gate electrodes 10, and the gate connection part 30.

As a result, an effect of an increase in the line width of each of the gate electrodes 10 provided on the top of the diffusion layer, caused by the corner rounding, is equally exerted on plural the gate electrodes, so that uniformity of the Tr characteristics of the semiconductor device 100 is not impaired.

Still further, the semiconductor device 100 according to the present embodiment is formed such that a distance between the corner (the inner corner 24, the outer corner 34) where the gate electrode 10 intersects the gate connection part 30, and the diffusion layer 50, as seen in a plan view, is the same at any of the corners.

Accordingly, respective portions of the corner roundings 80a, 80b, overlapping the diffusion layer 50, is identical in dimensions at any of the corners, thereby equalizing the gate length with respect to the respective gate electrodes 10.

### Second Exemplary Embodiment

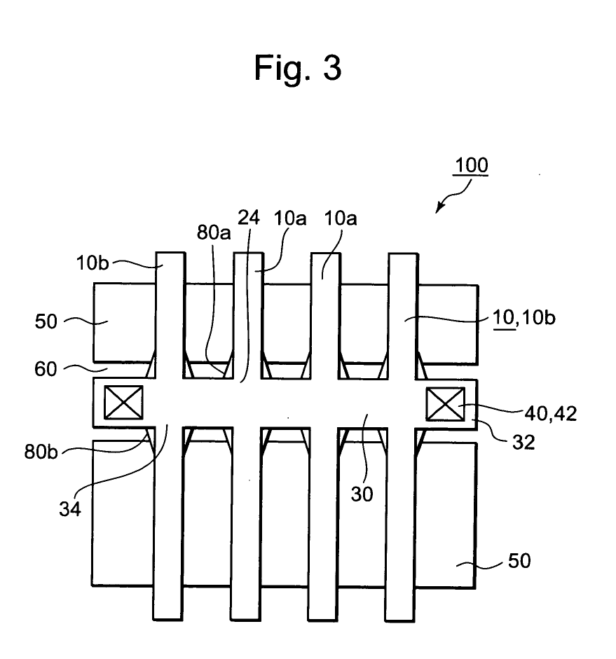

FIG. 3 is a schematic plan view showing an example of a semiconductor device 100 according to the present embodiment of the invention.

The present embodiment differs from the first exemplary embodiment in that a contact part 40, and a contact plug 42 are disposed over a protrusion 32.

More specifically, with the protrusion 32 according to present embodiment, an outer corner 34, and a corner rounding 80b are formed at an intersection between the protrusion 32 and the gate electrodes 10b positioned at respective ends of the gate electrodes 10 disposed in plural columns, further making up an electrical conduction path leading from the gate electrode 10 to an interconnection (not shown) provided in an upper layer.

In such a case, the protrusion 32 is composed of an electrically conductive material. Accordingly, the protrusion 32 is preferably fabricated out of the same kind of electrically conductive material as that for the gate electrode 10, and the gate connection part 30, having electrical conductivity, and in the same layer where the gate electrode 10, and the gate connection part 30 are provided.

With the semiconductor device 100 according to the present embodiment of the invention, since the protrusion 32 is provided at the respective ends of the gate connection part 30, gate electrodes 10b positioned at the respective ends can be provided with an outer corner 34, and a corner rounding 80b, and the protrusion 32 can be utilized as space where a contact part 40 is disposed.

### Third Exemplary Embodiment

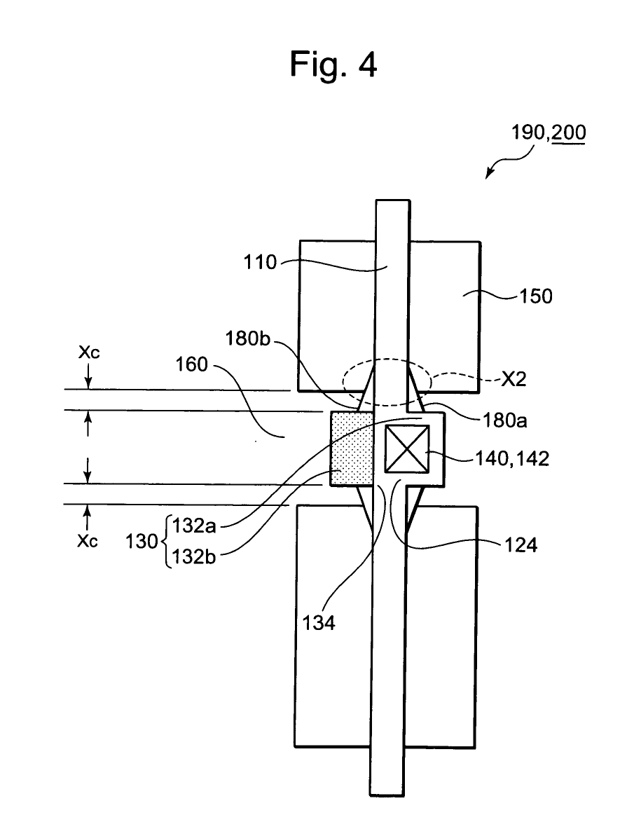

FIG. 4 is a schematic plan view showing an example of a semiconductor device 200 according to the present embodiment of the invention.

First, there is described an overview of the semiconductor device 200 according to the present embodiment.

The semiconductor device 200 includes the first transistor 90 according to the first exemplary embodiment, including the gate electrodes (first gate electrodes) 10, and the gate connection part (first gate connection part) 30, and a second transistor 190 including a second gate electrode 110 formed in a single column so as to spread across channel regions (diffusion layer 150) in an impurity diffusion layer, and device separation insulating regions (device separation insulating films 160).

The second gate electrode 110 according to the present embodiment has a feature in that the same has protrusions 132a, 132b (shown as highlighted, in the figure), protruding on respective sides thereof, in the direction of a gate length (the lateral direction in the figure), provided in the device separation insulating region.

Now, the semiconductor device 200 according to the present embodiment is described in detail.

The diffusion layer 150 over which the second gate electrode 110 is disposed in the single column may be identical to the diffusion layer 50 over which the first gate electrodes 10 are parallel-disposed in the plural columns, respectively, or may be a diffusion layer separately provided in the semiconductor substrate 70. Similarly, the device separation insulating film 160 over which the protrusions 132a, 132b are provided may be identical to the device separation insulating film 60 provided with the first gate connection part 30, or may be one separately provided in the semiconductor substrate 70.

The second gate electrode 110 disposed in the single column is provided with the protrusions 132a, 132b formed on respective sides thereof, in the direction of a line width, over the device separation insulating film 160, thereby forming a large-width part 130.

The large-width part 130 is electrically connected to an interconnection (not shown) provided in a layer above the second gate electrode 110 via a second contact part 140 provided so as to be offset toward one side of the second gate electrode 110, in the direction of the gate length, and a second contact plug 142 connected to the second contact part 140.

In the case of the present embodiment, the second contact part 140 is offset in a protrusion direction (the rightward direction in the figure) of the protrusion 132a. And a corner rounding 80a occurs to a corner 124 corresponding to an intersection between the protrusion 132a, and the second gate electrode 110.

The protrusion 132a is formed to a protrusion length of magnitude enabling the second contact part 140 to be provided therein. In general, the protrusion 132a is formed such that the protrusion length corresponds to one to 1.5 times as long as the gate length of the second gate electrode 110, or longer than that.

On the other hand, there is no particular limitation to a protrusion length of the protrusion 132b formed in such a way as to protrude in a direction opposite from an offset direction of the second contact part 140, however, if the protrusion length corresponds to one to 5 times as long as the gate length of the second gate electrode 110, this will enable a corner grounding 180b satisfactory in dimensions to be formed. Further, if the protrusion length corresponds to one to 2.5 times as long as the gate length, then this will prevent a pattern area of the second transistor 190 from becoming excessively large.

Now, there is described an operation effect of the semiconductor device 200 according to the present embodiment of the invention.

First, there is the case where the second contact plug 142 is provided so as to be offset toward one side (in the rightward direction in the figure) of the second gate electrode 110, in the direction of a width, for the sake of convenience, and so forth, in designing, or manufacturing. In such a case, if the protrusion 132a is formed in such a way as to protrude toward the one side only, it is possible to secure the second contact part 140 as the footprint of the second contact plug 142.

In such a case, however, upon patterning a circuit pattern of the second transistor 190 by photolithography, the corner grounding 180a is formed only at the corner 124 between the second gate electrode 110, and the protrusion 132a owing to the optical proximity effect, thereby creating a problem.

This is because if the protrusion 132a is present only on one side of the second gate electrode 110, then this will cause the corner grounding 180a to be formed on the one side only, so that the second gate electrode 110 will differ in line width from the first gate electrode 10.

Accordingly, with the semiconductor device 200 according to the present embodiment, wherein the second contact plug 142 is provided so as to be offset toward the one side of the second gate electrode 110, the protrusion 132b serving as a dummy gate is formed on the opposite side of the protrusion 132a in order to equally form the corner groundings 180a, 180b on the respective sides of the second gate electrode 110, in the direction of the width thereof.

By so doing, the corner groundings 180a, 180b are formed on the respective sides of the second gate electrode 110, in the direction of the width thereof, and the line width of the first gate electrode 10 provided in the first transistor 90 becomes equal to that of the second gate electrode 110 provided in the second transistor 190. Accordingly, with the semiconductor device 200 wherein the first transistor 90, and the second transistor 190 coexist, it is possible to equalize the Tr characteristics thereof.

Further, with the present embodiment, a direction in which a boundary line between the diffusion layer 150, and the device separation insulating film 160 is extended coincides with the protrusion direction of the protrusions 132a, 132b, as shown in FIG. 4. By so doing, a distance between the diffusion layer 150, and the corner 124, as seen in a plan view, becomes equal to a distance between the diffusion layer 150, and a corner 134, as seen in a plan view.

Accordingly, if the corner groundings 180a, 180b are each formed to such dimensions as to overlap the diffusion layer 150, then the corner groundings 180a, 180b, in a state overlapping the diffusion layer 150, become identical in shape and dimensions to each other.

Further, with the semiconductor device 200 according to the present embodiment, a distance (Xc) between the diffusion layer 150, and the large-width part 130 in the second transistor 190, as seen in a plan view, is equal to the distance (Xa) between the diffusion layer 50, and the first gate connection part 30 in the first transistor 90, as seen in a plan view.

Accordingly, with the semiconductor device 200 according to the present embodiment, even in the case of occurrence of relatively large corner roundings overlapping the diffusion layer 150 owing to relationship with the exposure light wavelength, and so forth, dimensions of the overlapping part as above in the first transistor 90 can be rendered equal to those in the second transistor 190, corresponding thereto. As a result, the gate length of the second gate electrode 110 in a region (region X2 in FIG. 4) where the corner groundings 180a, 180b have been formed over the diffusion layer 150 becomes equal to the gate length of the first gate electrode 10 in the first transistor 90. This will lead to less fluctuation in the Tr characteristics of the semiconductor device 200 wherein the first transistor 90, and the second transistor 190 coexist.

### Fourth Exemplary Embodiment

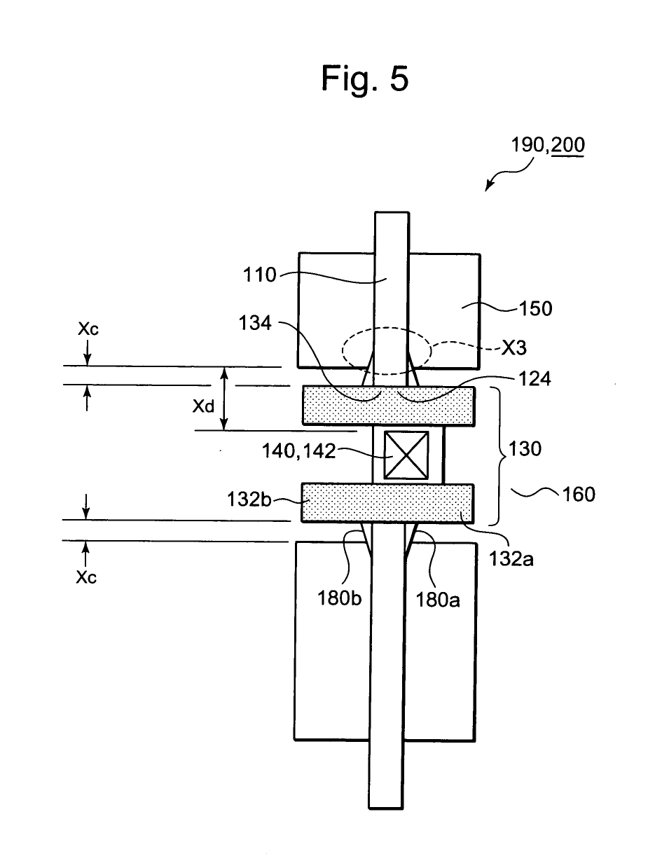

FIG. 5 is a schematic plan view showing an example of a semiconductor device 200 according to a fourth exemplary embodiment of the invention.

The semiconductor device 200 according to the present embodiment has a feature in that a distance (Xd) between a diffusion layer 150, and a second contact part 140 in the second transistor 190, as seen in a plan view, is greater than a distance (Xb: refer to FIG. 2) between the diffusion layer 50, and the contact part (first contact part) 40 in the first transistor 90, and a distance (Xc) between the diffusion layer 150, and a large-width part 130 in the second transistor 190, as seen in a plan view, is equal to the distance (Xa) between the diffusion layer 50, and the first gate connection part 30 in the first transistor 90, as seen in a plan view.

The semiconductor device 200 according to the present embodiment is concerned with a semiconductor device wherein the first transistor 90, and the second transistor 190 coexist as is the case with the third exemplary embodiment of the invention. With the present embodiment, a large-width part 130 is disposed so as to be shifted from a second contact part 140 in the direction of a gate width (the vertical direction in the figure) in order to render corner groundings 180a, 180b, occurring in the second transistor 190, equivalent in shape and dimensions to the corner roundings 80a, 80b, occurring in the first transistor 90. More specifically, as to respective portions of protrusions 132a, 132b (shown as highlighted, in the figure), protruding from a second gate electrode 110, in the direction of a gate length, a sufficient length thereof is first secured, and the large-width part 130 is disposed such that the distance Xc between the diffusion layer 150, and the large-width part 130 in the second transistor 190, as seen in a plan view, becomes equivalent to the distance (Xa) between the diffusion layer 50, and the first gate connection part 30 in the first transistor 90, as seen in a plan view.

With the semiconductor device 200 according to the present embodiment, the distance (Xd) between the diffusion layer 150, and the second contact part 140 in the second transistor 190, as seen in a plan view, is greater than the distance (Xb) between the diffusion layer 50, and the first contact part 40 in the first transistor 90.

Accordingly, assuming that the large-width part 130 is formed by causing the protrusions 132a, 132b to protrude from the second gate electrode 110 in the direction of the gate length only, a distance between the diffusion layer 150, and the large-width part 130, as seen in a plan view, will be greater than a distance between the diffusion layer 50, and the first contact part 40. In this case, the corner groundings 180a, 180b each will not overlap a region (region X3 in FIG. 5) of the diffusion layer 150, proximate to the large-width part 130, or part of the regions, overlapped by the corner groundings 180a, 180b, respectively, will be smaller in dimensions than that in the case of the first transistor 90, whereupon the gate length in the first transistor 90 will come to differ from the gate length in the second transistor 190, so that non-uniformity occurs to the Tr characteristics.

In contrast, with the semiconductor device 200, the large-width part 130 is formed by causing the protrusions 132a, 132b to be protruded from the second gate electrode 110 not only in the direction of the gate length but also in the direction of a gate width over a device separation insulating film 160, thereby rendering the distance Xc between the diffusion layer 150, and the large-width part 130, as seen in a plan view, equal to the distance Xa between the diffusion layer 50, and the first gate connection part 30, as seen in a plan view. In so doing, respective portions of the corner groundings 180a, 180b, overlapping the diffusion layer 150, in the second transistor 190, can be rendered equivalent in shape and dimensions to the respective portions of the corner groundings 80a, 80b, overlapping the diffusion layer 50, in the first transistor 90.

Accordingly, with the semiconductor device 200 wherein the first transistor 90, and the second transistor 190 coexist, it is possible to reduce fluctuation in the Tr characteristics thereof.

### Fifth Exemplary Embodiment

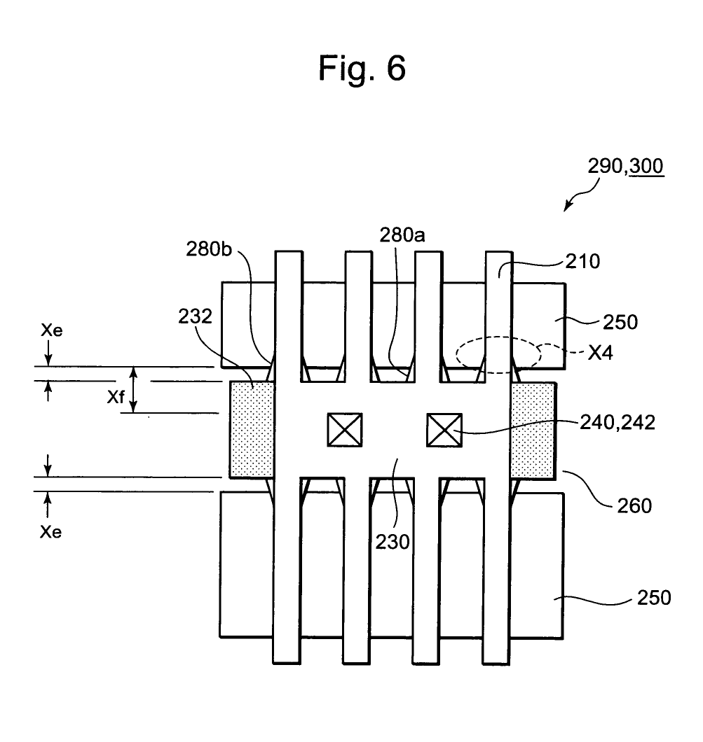

FIG. 6 is a schematic plan view showing an example of a semiconductor device 300 according to a fifth exemplary embodiment of the invention.

The semiconductor device 300 includes the first transistor 90 including the first gate electrodes 10, and the first gate connection part 30, and a third transistor 290 including third gate electrodes 210 and a third gate connection part 230.

As is the case with the first gate electrodes 10, the third gate electrodes 210 are formed so as to be provided in plural columns, respectively, and to be lined up along the direction of a gate length, each spreading across channel regions (diffusion layers 250) in an impurity diffusion layer, and device separation insulating regions (device separation insulating films 260).

As is the case with the first gate connection part 30, the third gate connection part 230 is provided in the device separation insulating film, and in the same layer where the third gate electrodes 210 are disposed, for electrically connecting the third gate electrodes 210 with each other, the third gate connection part 230 having a protrusion 232 (shown as highlighted, in the figure) protruding outward in the direction of the gate length from the third gate electrodes 210 positioned at the respective outermost ends of the plural columns.

The third gate electrodes 210 is electrically connected to an interconnection (not shown) provided in an upper layer of the third gate electrodes 210 via a third contact part 240 provided in the third gate connection part 230.

Further, with the semiconductor device 300 according to the present embodiment has a feature in that a distance (Xf) between the diffusion layer 250, and the third contact part 240, as seen in a plan view, is greater than the distance (Xb: refer to FIG. 2) between the diffusion layer 50, and the first contact part 40, and a distance (Xe) between the diffusion layer 250, and the third gate connection part 230, as seen in a plan view, is equal to the distance (Xa) between the diffusion layer 50, and the first gate connection part 30, as seen in a plan view.

The semiconductor device 300 according to the present embodiment includes two different types of transistors, each including the gate electrodes disposed in the plural columns, respectively, and gate connection parts for connecting the gate electrodes with each other, and the gate connection parts each are provided with protrusions protruding in the direction of a gate length. By so doing, the gate electrodes positioned at the respective ends of the plural columns can be provided with a corner (an outer corner).

Further, with the semiconductor device 300, a line width of the third gate connection part 230 is set such that a distance between the gate connection part, and the diffusion layer, at a corner (an inner corner, an outer corner) of the first transistor 90 is identical to that at a corner of the third transistor 290.

In other words, the third gate connection part 230 according the present embodiment is formed in such a way as to be protruded in the direction of a gate width to have a large width in excess of a line width necessary for connecting the third gate electrodes 210 with each other, and for disposing the third contact parts 240 therein, such that the distance from the third gate connection part 230 up to the diffusion layer 250, as seen in a plan view, will become equivalent to a distance corresponding thereto with respect to the first transistor 90.

Further, the semiconductor device 300 has the contact parts (the first contact part 40, the third contact part 240) positioned at different distances from the diffusion layers 50, 250, respectively, as seen in a plan view, however, the gate connection parts (the first gate connection part 30, the third gate connection part 230) are disposed at an equal distance from the diffusion layers 50, 250, respectively, as seen in a plan view.

Further, the diffusion layer 250 over which the third gate electrodes 210 are disposed in the plural columns, respectively, may be identical to the diffusion layer 50 over which the first gate electrodes 10 are parallel-disposed in the plural columns, respectively, or may be a diffusion layer separately provided in the semiconductor substrate 70. Similarly, the device separation insulating film 260 over which the third gate connection part 230 is provided may be identical to the device separation insulating film 60 provided with the first gate connection part 30, or may be one separately provided in the semiconductor substrate 70.

There is no particular limitation to the number of the third gate electrodes 210, and the number of the third gate electrodes 210 may be identical to the number of the first gate electrodes 10, as shown in FIG. 6, or may differ therefrom.

Further, there is no particular limitation to the number of the third contact parts 240, and the number of the third contact plugs 242 either, and as shown in FIG. 6, the number of the third contact parts 240, and the number of the third contact plugs 242 may be identical to the number of the first contact parts 40, and the number of the first contact plugs 42, or may differ therefrom.

The protrusion 232 to be formed in the third gate connection part 230 may be formed so as to protrude outward from the third gate electrodes 210 positioned at the respective ends of the third gate connection part 230, or may be formed only on one side of the third gate connection part 230.

If the protrusion 232 is provided at the respective ends of the third gate connection part 230, as in the case of the present embodiment, in particular, then the corner can be provided on both sides of the line width of each of the third gate electrodes 210 disposed in the plural columns, respectively, as is the case with the first exemplary embodiment of the invention.

With the semiconductor device 300 according to the present embodiment, the distances Xa, Xe from the diffusion layers 50, 250 up to the gate connection parts (the first gate connection part 30, the third gate connection part 230), respectively, as seen in a plan view, are equal to each other. Accordingly, even in the case of plural transistors wherein a distance between a diffusion layer, and a contact part, as seen in a plan view, differ from one another, each having gate electrodes disposed in plural columns, respectively, it is possible to equalize respective gate lengths of all the gate electrodes in a region (the region X1 in FIG. 1, the region X4 in FIG. 6) where the corner roundings overlapping the top of diffusion layer have been formed.

With the invention described in the foregoing, if the protrusion that is protruded on both sides of the gate electrode, in the direction of the gate length, is provided as in the respective cases of the first to third exemplary embodiments, then it is possible to cause the optical proximity effect to occur to both sides of the gate electrode, thereby forming the corner roundings. By so doing, a bulge of the gate electrode equally occurs to any of the gate electrodes, thereby equalizing the line widths of the gate electrodes.

Then, in the case of the corner roundings overlapping the diffusion layer, overlapping parts by the gate electrode become identical in dimensions to one another, so that the gate lengths can be equalized, thereby checking fluctuation in the Tr characteristics.

Further, with the transistor as is the case with the fourth, and fifth exemplary embodiments, respectively, wherein the distance between the diffusion layer, and the contact part, as seen in a plan view, differs from the distance corresponding thereto in other transistors, the overlapping parts can be rendered identical in dimensions to one another, by providing the protrusions and the connection part in such a way as to be protruded in both the direction of the gate length and the direction of the gate width. As a result, fluctuation in the gate length among the respective gate electrodes can be checked, thereby equalizing the Tr characteristics.

It is to be understood that the invention is not limited to those embodiments described in the foregoing and that various changes and modifications may be made in the invention provided that the object of the invention is attained.

For example, with the first or the second exemplary embodiment of the invention, the protrusion 32 may be provided so as to protrude outward from an end of the gate connection part 30, only on one side thereof, in the direction of the gate length. By so doing, with respect to the gate electrode 10 positioned at the end of the gate connection part 30, on the one side thereof, where the protrusion 32 is provided, a corner and a corner rounding are formed on both sides of the line width of the gate electrode 10 as is the case with the other gate electrodes 10 positioned inside of the plural columns, so that it is possible to equalize to an extent the Tr characteristics of the semiconductor device 100 as a whole.

Further, with the first to fifth exemplary embodiments, respectively, respective shapes of the protrusions 32, 132a, 132b, 232 each are not limited to the shape of a rectangle shown in FIGS. 1, 3, 4, 5, 6, respectively. There is no particular limitation to the shape of the protrusion, and if a protrusion is in such a shape as to enable the outer corner to be formed on the gate electrode, and to render the distance between the outer corner, and the diffusion layer equivalent to the distance between the inner corner, and the diffusion layer, the protrusion will suffice, and there is no particular limitation to the shape thereof Furthermore, portions of the protrusion, protruding outward from the corner roundings 80b, 180b, and 280b, respectively, may be removed after formation of the gate electrodes, and the gate connection part.

Further, with the third exemplary embodiment, the second contact part 140 is provided only inside between the second gate electrode 110, and the protrusion 132a, as shown in FIG. 4, however, the invention is not limited thereto. For example, the second contact part 140 may be provided such that a part thereof spread onto the protrusion 132b as long as the center of the second contact part 140 is offset toward one side of the second gate electrode 110 (a side thereof adjacent to the protrusion 132a), that is, a part of the footprint of the second contact part 140 may be included in the protrusion 132b.

Still further, with the fourth exemplary embodiment, the large-width part 130 is formed in such a way as to swell out toward only one side (in the figure, the rightward side) of the second gate electrode 110, as shown in FIG. 5, however, the invention is not limited thereto, and the large-width part 130 may be formed in such a way as to swell out toward both sides of the center line of the second gate electrode 110. Yet further, with the fourth exemplary embodiment, FIG. 5 shows a state where the protrusion 132a protrudes beyond the large-width part 130, in the direction of the gate length, however, the invention is not limited thereto.

Furthermore, in the semiconductor device according to the invention, any of the transistors having various transistor structures described in the foregoing may be singly provided, or mixture of optional two kinds or more of the transistors may be provided.

What is claimed is:

1. A semiconductor device, comprising:
a plurality of gate electrodes disposed in a column, over a semiconductor substrate; and
a gate connection portion provided with a same layer where the plurality of gate electrodes are placed, for electrically connecting the gate electrodes, the gate connection portion including a protrusion protruding outwardly in a direction of a gate length from the gate electrode positioned at an outermost end of the plurality of the gate electrodes.

2. A semiconductor device according to claim 1, wherein the protrusion protrudes outwardly in the direction of the gate length from gate electrodes positioned at respective ends of the plurality of the gate electrodes.

3. A semiconductor device according to claim 1, wherein the gate electrode is electrically connected to an interconnection provided in an upper layer of the gate electrode via a contact portion provided in the gate connection portion, and the contact portion is provided inside gate electrodes positioned at respective ends of the plurality of the gate electrodes.

4. A semiconductor device according to claim 1, wherein the semiconductor substrate includes an impurity diffusion region, and a device separation insulating region placed adjacent to the impurity diffusion layer where the gate connection portion is formed, the respective gate electrodes are formed so as to spread across the impurity diffusion region and the device separation insulating region, and a corner rounding overlapping the impurity diffusion region is formed at any of corners between the respective gate electrodes, and the gate connection portion.

5. A semiconductor device according to claim 4, further comprising:
a first transistor including the plurality of gate electrodes and the gate connection portion;
a second transistor including a second gate electrode formed in a single column so as to spread across channel regions and the device separation insulating region, wherein the second gate electrode includes a plurality of protrusions protruding on respective sides thereof, in the direction of a gate length, provided on the device separation insulating region.

6. A semiconductor device according to claim 5, wherein the second gate electrode is electrically connected to an interconnection provided in an upper layer of the second gate electrode, via a second contact portion provided so as to be offset from a center line of the second gate electrode toward one side thereof, in the direction of the gate length.

7. A semiconductor device according to claim 5, wherein a distance in a gate width between the impurity diffusion region and the protrusion in the second transistor, is substantially equal to a distance in a gate width between the impurity diffusion region and the gate connection portion in the first transistor.

8. A semiconductor device according to claim 6, wherein the plurality of gate electrodes in the first transistor are electrically connected to an interconnection provided in an upper layer of the gate electrode via a first contact portion provided in the gate connection portion,
a distance between the impurity diffusion region and the second contact portion of the second transistor is greater than a distance between the impurity diffusion region and the first contact portion of the first transistor, and
a distance between the impurity diffusion region and the protrusion, in the second resistor is substantially equal to a distance between the impurity diffusion region and the gate connection portion, in the first resistor.

9. A semiconductor device according to claim 5, wherein a length of the protrusion of the first transistor and the second transistor, is 1 to 2.5 times as large as the gate length of the respective gate electrodes.

10. A semiconductor device according to claim 4, further comprising:
a first transistor including the plurality of gate electrodes and the gate connection portion; and
a second transistor including:
a plurality of second gate electrodes provided in a column, each spreading across a diffusion region and a device separation insulating region, and
a second gate connection portion provided in the device separation insulating region and in a same layer where the second gate electrodes are disposed, for electrically connecting the second gate electrodes with each other, the second gate connection portion having a protrusion protruding outwardly in the direction of a gate length from the second gate electrodes positioned at the respective outermost ends of the plurality of the second gate electrodes,
wherein the second gate electrodes are electrically connected to an interconnection provided in an upper layer of the second gate electrodes via a second contact portion provided in the second gate connection portion,
a distance between the impurity diffusion region and the second contact portion of the second transistor, is greater than a distance between the impurity diffusion region and the contact portion of the first transistor, and
a distance between the impurity diffusion region and the second gate connection portion of the second transistor, is substantially equal to a distance between the impurity diffusion region and the gate connection portion of the first transistor.

11. A semiconductor device, comprising:
an impurity diffusion region;
an element isolation region surrounding the impurity diffusion region;
a single gate electrode extending in a straight line in a first direction, the gate electrode including a first portion extending across the impurity diffusion region, and a second portion arranged on the element isolation region;
a first projection portion projecting from the second portion in a second direction perpendicular to the first direction at a first side of surfaces divided by the gate electrode to provide a contact portion where a contact hole is provided thereon; and
a second projection portion projecting from the second portion in the second direction at a second side of the surfaces enough to substantially balance between an optical proximity effect caused by the first portion and an optical proximity caused by the second portion.

12. The semiconductor device as claimed in claim 11, wherein the second portion is substantially provided in an axisymmetric relationship with the first portion against the gate electrode.

13. The semiconductor device as claimed in claim 11, wherein the second portion is provided between the contact portion and the impurity diffusion region in the first direction, the semiconductor device further comprising:
a third portion extending from the second portion in the second direction so as to place the first side so that the third portion is located between the contact portion and the impurity diffusion region in the first direction.

14. A semiconductor device, comprising:
an impurity diffusion region;
an element isolation region surrounding the impurity diffusion region;
a plurality of gate electrodes each extending in a first direction, each of the gate electrodes including a first portion extending across the impurity diffusion region, and a second portion arranged on the element isolation region, the second portions being connected to each other with a layer which is a same level of the second portion; and
a projecting portion projected, in a second direction perpendicular to the first direction so as to pull away from the layer, from the second portions of the gate electrodes positioned at outermost ends among the plurality of gate electrodes, enough to substantially balance between an optical proximity effect caused by the layer and an optical proximity caused by the projecting portion.
